(19) United States
(12) Patent Application Publication
(10) Pub. No.: US 2016/0231359 A1
(43) Pub. Date: Aug. 11, 2016

(54) CURRENT DETECTION DEVICE, ITS MANUFACTURING METHOD, AND ITS MOUNTING STRUCTURE

(71) Applicant: KOA CORPORATION, Ina-shi (JP)

(72) Inventors: Keishi Nakamura, Ina-shi (JP); Masakazu Ito, Ina-shi (JP); Kenji Kameko, Ina-shi (JP)

(73) Assignee: KOA CORPORATION, Ina-shi (JP)

(21) Appl. No.: 15/133,759

(22) Filed: Apr. 20, 2016

Related U.S. Application Data
(63) Continuation of application No. PCT/JP2014/076535, filed on Oct. 3, 2014.

(30) Foreign Application Priority Data
Oct. 25, 2013 (JP) 2013-222556

(51) Int. Cl. G01R 15/14; G01R 19/00

(52) U.S. Cl. CPC G01R 15/146; G01R 19/0092

(57) ABSTRACT

Provided is a current detection device, which is capable of measuring a large current with a high degree of accuracy and reliability. The current detection device comprises a first wiring member consisting of a highly conductive material, a second wiring member consisting of a highly conductive material, and a resistance body consisting of a metal material having a smaller temperature coefficient of resistance than the highly conductive materials used in the wiring members. The first wiring member and the second wiring member are welded to the resistance body, and the second wiring member is longer than the first wiring member. The second wiring member has a plurality of bent portions. The plurality of bent portions includes portions bent to horizontal direction and portions bent to vertical direction. Voltage detection terminals are formed in the vicinity of the resistance body on the first and second wiring members.

### TECHNICAL FIELD

The present invention relates to a current detection device, and particularly relating to the device, which is capable of measuring a large current with a high degree of accuracy while using the device as a wiring for supplying a current.

### BACKGROUND ART

Current detections are adopted for detecting a charge and discharge current in a battery, for detecting a motor current for driving electric motor vehicles and hybrid motor vehicles, for detecting a current in electric equipment such as air conditioner, solar cell system or so on. The current is detected by measuring a voltage between both ends of resistance body of the shunt resistor caused by the current flowing therethrough.

Busbars are selected as a route of a path for supplying a current from a power source such as battery to an electrical equipment. A shunt resistor might be connected to the busbar for detecting a current flowing through the busbar. In the cases, the busbar and the shunt resistor might be connected by screw stop or by soldering. (see Japanese laid open patent publication 2011-3694 and H6-224014 etc.)

However, those connection methods increase connection portions, which become a factor of a heat generation. The methods may cause a problem of securing connection reliability. Therefore, a current detection device, which can use for detecting a large current with high reliability, is desired.

Forming a shunt resistor at a portion inside of a busbar is proposed by forming a long hole at the portion (see Japanese laid open patent publication 2001-349907). However, as to the busbar, a metal of low resistivity such as copper is generally used. The metal such as copper has high resistance temperature coefficient, then it is difficult to detect a current with high accuracy. Therefore highly accurate current detection is difficult for forming a shunt resistor portion inside of the busbar with using the metal material such as copper for the portion.

### SUMMARY OF INVENTION

### Technical Problem

The invention has been made basing on above-mentioned circumstances. Therefore an object of the invention is to provide a current detection device, its manufacturing method, and its mounting structure, which can measure a current flowing through a busbar with high accuracy and with high reliability.

### Solution to Problem

The current detection device of the invention comprises a first wiring member consisting of a highly conductive material, a second wiring member consisting of a highly conductive material, and a resistance body consisting of a metal material having a smaller temperature coefficient of resistance than the highly conductive materials used in the wiring members, wherein the first wiring member and the second wiring member are welded to the resistance body, and the second wiring member is longer than the first wiring member.

The manufacturing method of the current detection device of the invention comprises preparing a first wiring member consisting of a metal material, a second wiring member consisting of a metal material, and a resistance body consisting of a metal material having a smaller temperature coefficient of resistance than the highly conductive materials used in the wiring members, the first and second wiring members being more highly conductive than the resistance body, and welding the first and second wiring members to the resistance body. The first wiring member is a shorter one, and can be standardized as a semifinished product with the resistance body so as to be easy for mass production. The second wiring member is a longer one, and having a plurality of bent portions, which are bent to horizontal and/or vertical directions. The second wiring member is formed so as to be matching with users specifications. Then both ends of the busbar consisting of the first wiring member, the resistance body, and the second wiring member can be directly connected between devices for detecting a current flowing therethrough.

According to the invention, because both ends of the resistance body are strongly fixed to the wiring members, the function of the bus bar can be integrated with the function of the shunt resistor, and the connections become unnecessary. Therefore the number of parts can be decreased, the mounting cost can be decreased, and the connection reliability can be improved. Because the resistance body consisting of metal material having a small resistance temperature coefficient is built in the bus bar, detection of a large current with high accuracy becomes possible as well as the shunt resistor. Thus above mentioned problems have been solved.

Because the second wiring member is a longer one, it becomes possible to make the wiring member a complicated bent shape. That is, it becomes possible to make the structure of the wiring member being matched with user's specifications. The first wiring member is a shorter one, and can be standardized as a semifinished product with the resistance body. Therefore a part including the first wiring member and the resistance body has high mass productivity and a part including the second wiring member has enhanced custom designability. Thus coexisting of mass productivity and custom designability becomes possible. Further by forming a plurality of bent portions in the second wiring member, it becomes possible to ease concentration of stress to welded portions of the resistance body and the wiring member.

### BRIEF DESCRIPTION OF DRAWINGS

FIG. 1 shows a perspective view of a current detection device of first embodiment of the invention.

FIG 2 Upper part of FIG. 2 shows a plan view of FIG. 1, lower left part of FIG. 2 shows a front view of FIG 1, and lower right view of FIG. 2 shows a side view of FIG. 1.

FIG. 3 shows a perspective view of a current detection device of second embodiment of the invention.

FIG. 4 Upper part of FIG. 4 shows a plan view of FIG. 3, and lower part of FIG. 4 shows a front view of FIG. 3.

FIG. 5 shows a perspective view of a current detection device of third embodiment of the invention.

FIG. 6 shows a perspective view of a current detection device of fourth embodiment of the invention.

FIG. 7 shows a perspective view of a current detection device of fifth embodiment of the invention.

FIG. 8 shows a perspective view of voltage detection terminals of another embodiment of the invention.

### DESCRIPTION OF EMBODIMENTS

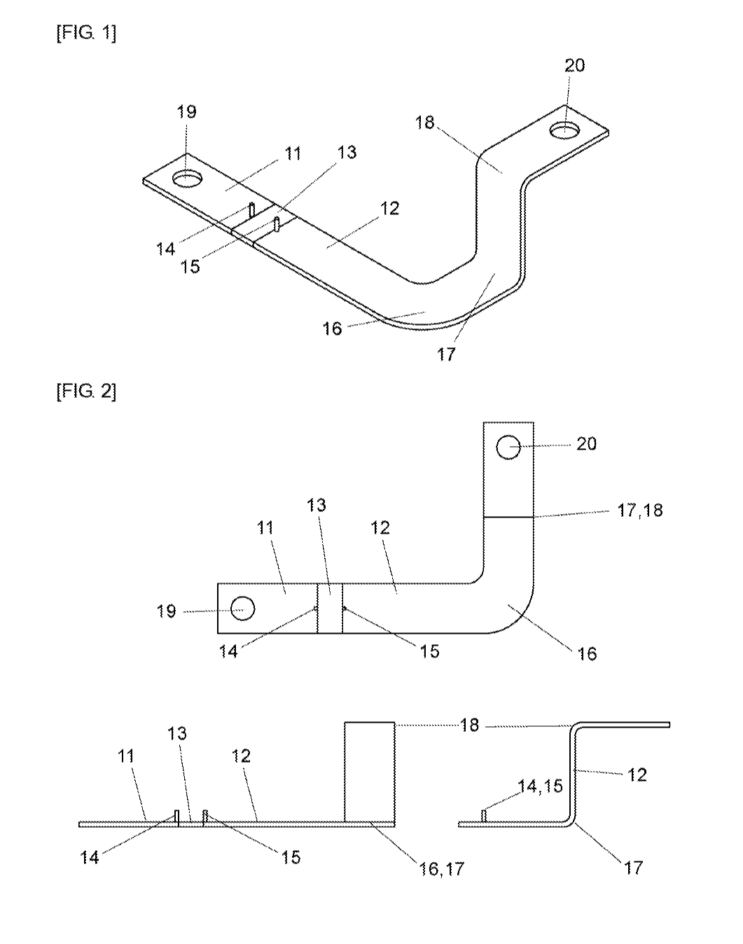

Embodiments of the invention will be described below with referring to FIG. 1 through FIG. 8. Like or corresponding parts or elements will be denoted and explained by same reference characters throughout views.

FIGS. 1 and 2 show a current detection device of first embodiment, which measures a current flowing through the busbar. A resistance body 13 is welded and fixed between first wiring member 11 and second wiring member 12, which is longer than first wiring member 11. That is, the current detection device builds in the shunt resistor (resistance body) 13 between the wiring members 11, 12. And the whole structure of the current detection device consists of a busbar.

The first and second wiring members 11,12 are strip (busbar)-shaped highly conductive metal material consisting of copper, copper system alloy, or aluminum etc. “Highly conductive” means that electroconductivity is high, and that conductivity of wiring members are higher than conductivity of resistance body 13. The resistance body 13 consists of metal resistance alloy material such as Cu—Mn system alloy, Cu—Ni system alloy, or Ni—Cr system alloy, which has extremely lower resistance temperature coefficient than metal material such as copper etc.

Both end faces of the resistance body 13 are abutted and welded to end faces of the wiring members 11,12, and strongly bonded surfaces are formed. The welding may use electron beam welding, laser beam welding, brazing or soldering, etc. Further, pressure bonding may be used by contacting end faces of resistance body and wiring members and pressurizing to be bonded.

A pair of voltage detection terminals 14,15 is installed in the wiring member 11,12 near the resistance body 13. The current flowing through the wiring member 11,12 flows through the resistance body 13, and the voltage caused at th ends of the resistance body 13 is detected by voltage detection terminals 14,15. That is, because the wiring members carry out the function of the electrodes or the terminals of shunt resistors, the function of shunt resistors can be integrated with the function of the busbar. Then connection portion between a shunt resistor and a busbar becomes unnecessary, and number of parts can be decreased. Thus, the current flowing through the busbar can be measured with high accuracy and high reliability.

The second wiring member 12 is longer than the first wiring member 11. The second wiring member 12 has a plural of bent portions as shown in FIG. 1. A bent portion 16 is bent in a horizontal plane, and a bent portion 17 is bent from a horizontal plane to a vertical plane. And a bent portion 18 is bent from a vertical plane to a horizontal plane.

Because the longer wiring member 12 has a plural of bent portions 16, 17, 18, the wiring member 12 can be formed to adapt to custom design bent shapes according to user's specifications. Thus the equipment, which installs the wiring member 12, can be made to small and compact. Further by forming a plural of bent portions in the wiring member, a stress applied to the busbar can be dispersed. Further a stress applied to junction surfaces between resistance body 13 and wiring members 11,12 can be decreased.

Because both ends of wiring members 11,12 have holes 19,20, both ends of the busbar having the shunt resistor function (that is, the current detection device) can be directly connected between devices for detecting a current flowing therethrough with bolt fixing etc. “Between devices for detecting a current flowing therethrough” includes “between a battery and a chassis ground for detecting a current flowing therethrough”, “between a battery and an inverter device for detecting a current flowing therethrough”, or so on.

According to prior art technology, a pair of devices for detecting a current flowing therethrough is connected with a serial connection of a shunt resistor and a busbar or a wiring. However, according to the invention, the pair of devices is connected therebetween with only the current detection device for detecting a current flowing therethrough. That is, the mounting structure of the invention can save the number of parts, decrease the mounting cost, and increase the connection reliability. Further without having the holes 19,20, both ends of the busbar having the shunt resistor function can be connected between the devices with welding etc.

The second wiring member 12 is longer than the first wiring member 11, and long current detection device like a busbar is realized as a whole. The resistance body 13 is positioned near one of the devices, to detect the current because the first wiring member 11 is short. Then heat generation at the resistance body 13 can be easily absorbed into one of the devices.

By making the first wiring member 11 a shorter one, the first wiring member 11 including the resistance body 13 can be standardized, then manufacturing process for mass production becomes easy. By making the second wiring member 12 a longer one, it becomes possible to make the second wiring member a complicated bent shape. That is, it becomes possible to make the structure of the second wiring member being adapted to user's specifications. Thus, as to the busbar having the current detection function, the coexisting of mass productivity and the custom designability becomes possible.

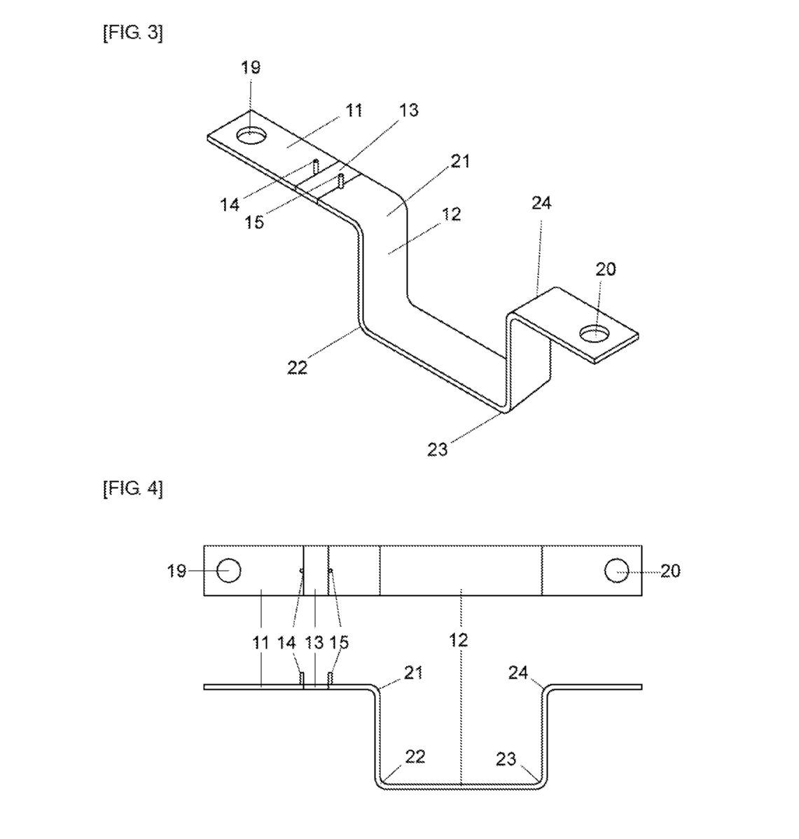

FIGS. 3 and 4 show a current detection device, which measures a current flowing through the busbar, according to the second embodiment. It is common with the first embodiment that the resistance body 13 is welded and connected between the first wiring member 11 and the second wiring member 12. In the embodiment, though a straight wiring member may be able to connect from hole 19 to hole 20, the wiring member 12 is made to a detour downward by installing bent portions 21,22,23,24 corresponding to user's specifications. Therefore, a small and compact design of the equipment becomes possible for the users, and the number of the parts can be reduced.

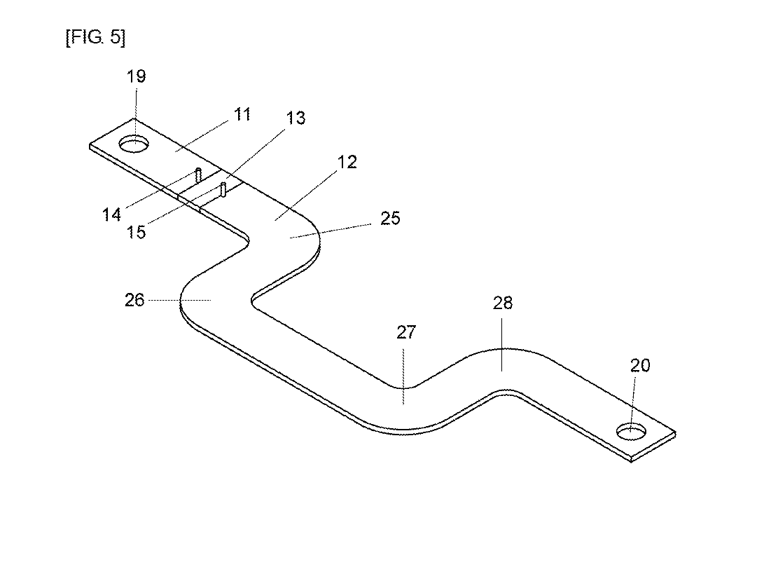

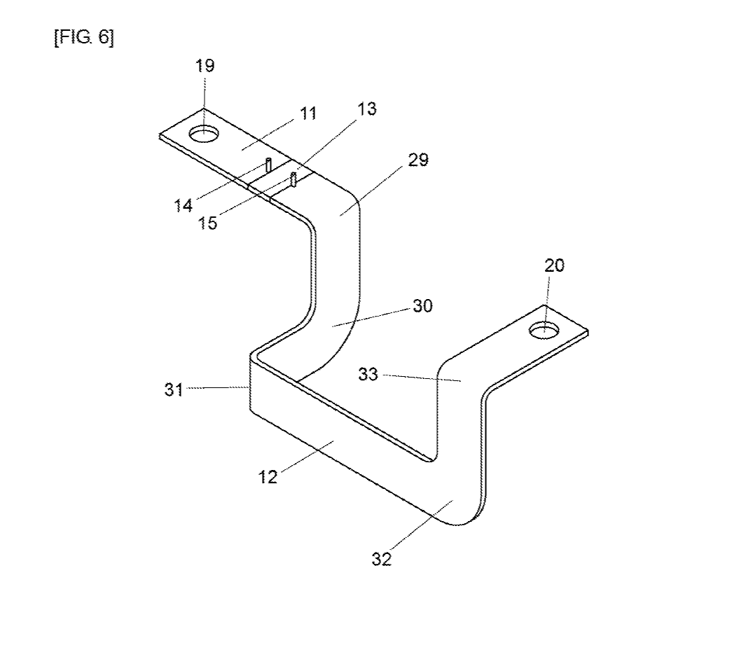

FIG. 5 shows a current detection device, which measures a current flowing through the busbar, according to the third embodiment. In the embodiment, the wiring member 12 is made to a detour on a side in the horizontal plane by installing bent portions 25,26,27,28 according to users specifications. Therefore, a small and compact design of the equipment becomes possible for the users, and the number of the parts can be reduced.

FIG. 6 shows a current detection device, which measures a current flowing through the busbar, according to the fourth embodiment. In the embodiment, bent portions 29,30,31, 32,33 are installed. The wiring member 12 is made to be bent at portion 29 from resistance body 13 side in horizontal plane to downward vertically, making a detour downward. The wiring member 12 is bent to horizontal direction at portion 30, is bent to vertical direction in a horizontal plane making a detour on a side in the horizontal plane at portion 31, is bent to vertical direction in the vertical plane at portion 32, and is bent to horizontal direction at portion 33.

Therefore, a small and compact design of the equipment becomes possible for the users, and the number of the parts can be reduced. The current detection device is formed to have bent portions, which detour obstacles, so as to attain compact design.

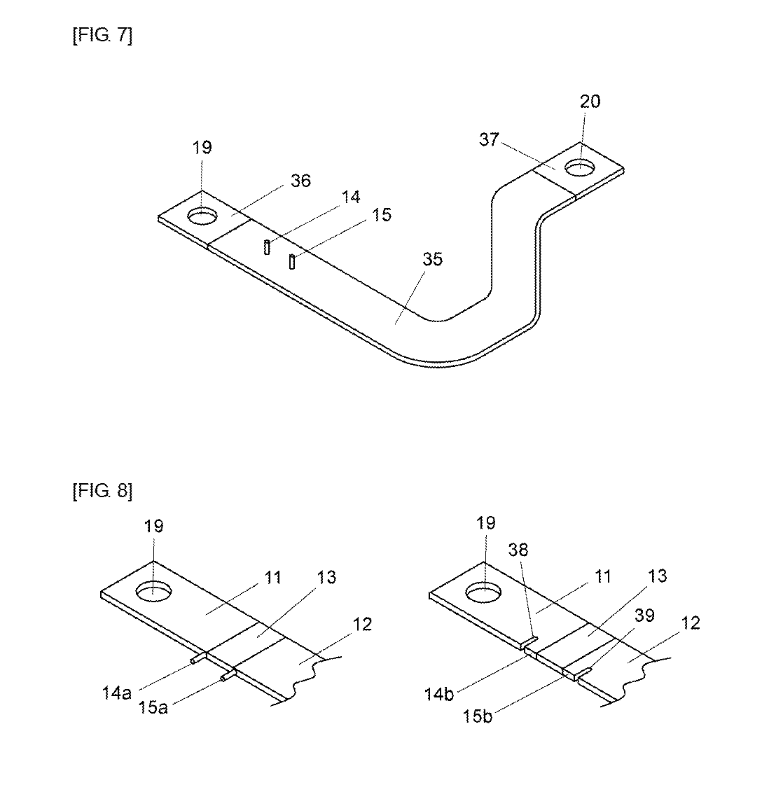

FIG. 7 shows a current detection device, which measures a current flowing through the busbar, according to the fifth embodiment. Entire surfaces of the wiring members 11,12 and the resistance body 13 is covered by a protective film 35 except holes 19,20 and their peripherals. Only voltage detection terminals 14,15 are projected from the protective film 35. Peripheral areas of hole 19,20, which are not covered by the protective film, are surface treated by plated film 36,37 such as Sn or Ni etc.

The entire busbar can be prevented from being oxidized by covering with protective film 35 and plated films 36,37. As to protective film 35, a nonconductive protective film, for example, coated film of inorganic material such as glass or ceramics etc. or nonconductive oxide film formed by alumite treatment etc. can be used.

According to the current detection devices as shown in FIGS. 1 through 7, all of the wiring member 11 and the resistance body 13 has same standardized common structure. Thus the wiring member 11 and the resistance body 13 or an intermediate member consisting of wiring member 11 and resistance body 13 being connected can be manufactured and stocked. When the wiring member 12, which is formed basing on users specification, is welded to the stocked parts, then finished product of the current detection device can be obtained. Efficiency of manufacturing the current detection device improves, and the current detection device having various shapes can be manufactured.

According to above embodiments, voltage detection terminals are projected on a surface of the wiring member vertically. However, voltage detection terminals 14,15 may be installed at vicinity of joint surface with resistance body on wiring members, and then constructions shown in FIG. 8 are possible. That is, left view in FIG. 8 shows that voltage detection terminals 14a,15a are projected on side surfaces of wiring members horizontally. Also, right view in FIG. 8 shows that installing cuts 38,39 in neighbor of joint surface with resistance body on wiring members, and making the portions between the cut and joint surface used as voltage detection terminals 14b,15b.

Although embodiments of the invention have been explained, however the invention is not limited to above embodiments, and various changes and modifications may be made within scope of the technical concepts of the invention.

### INDUSTRIAL APPLICABILITY

The invention can be suitably used for the current detection devices, which measure large currents flowing through the wiring members.

1. A current detection device comprising:
a first wiring member consisting of a highly conductive material,
a second wiring member consisting of a highly conductive material, and
a resistance body consisting of a metal material having a smaller temperature coefficient of resistance than the highly conductive materials used in the wiring members,
wherein the first wiring member and the second wiring member are welded to the resistance body, and the second wiring member is longer than the first wiring member.

2. The device of claim 1, wherein the second wiring member has a plurality of bent portions.

3. The device of claim 2, wherein the plurality of bent portions includes portions bent to horizontal direction and portions bent to vertical direction.

4. The device of claim 1, wherein voltage detection terminals are formed in the vicinity of the resistance body on the first and second wiring members.

5. The device of claim 1, wherein a nonconductive protective film is formed on the first wiring member, the resistance body, and the second wiring member.

6. The device of claim 5, wherein the first wiring member and the second wiring member are provided with holes, and peripheral areas of the holes are surface treated by a plated film.

7. A method for manufacturing a current detection device comprising:
preparing a first wiring member consisting of a metal material, a second wiring member consisting of a metal material, and a resistance body consisting of a metal material having a smaller temperature coefficient of resistance than the highly conductive materials used in the wiring members;
making the first wiring member welded to the resistance body:
making the second wiring member, which is longer than the first wiring member, to have a plural of bent portions toward a horizontal direction and/or a vertical direction; and
welding the second wiring member to the resistance body.

8. The method of claim 7, further comprising:
forming voltage detection terminals in the vicinity of the resistance body on the first and second wiring members.

9. A mounting structure of a current detection device, said device comprising:
a first wiring member consisting of a highly conductive material,
a second wiring member consisting of a highly conductive material, and
a resistance body consisting of a metal material having a smaller temperature coefficient of resistance than the highly conductive materials used in the wiring members,
wherein the second wiring member is longer than the first wiring member, and the second wiring member has a plurality of bent portions, and
wherein both ends of the first wiring member and the second wiring member are directly connected between devices for detecting a current flowing therethrough.

10. The mounting structure of claim 9, wherein the plurality of bent portions includes portions bent to horizontal direction and portions bent to vertical direction.

11. The mounting structure of claim 9, wherein voltage detection terminals are formed in the vicinity of the resistance body on the first and second wiring members.
